(19) United States
(12) Patent Application Publication
(10) Pub. No.: US 2012/0118225 A1
(43) Pub. Date: May 17, 2012

(54) EPITAXIAL GROWTH TEMPERATURE CONTROL IN LED MANUFACTURE

(75) Inventors: Wei-Yung HSU, Santa Clara, CA (US); Alain DUBOUST, Sunnyvale, CA (US); Hua CHUNG, San Jose, CA (US); Liang-Yuh CHEN, Foster City, CA (US); Donald J.K. OLGADO, Palo Alto, CA (US)

(73) Assignee: Applied Materials, Inc., Santa Clara, CA (US)

(21) Appl. No.: 13/231,852

(22) Filed: Sep. 13, 2011

Related U.S. Application Data
(60) Provisional application No. 61/383,669, filed on Sep. 16, 2010.

(51) Int. Cl. C30B 25/16; B05C 11/06; C30B 25/10; H01L 21/66

(52) U.S. Cl. 117/86; 118/667; 257/E21.53

(57) ABSTRACT

Apparatus and method for control of epitaxial growth temperatures during manufacture of light emitting diodes (LEDs). Embodiments include measurement of a substrate and/or carrier temperature during a recipe stabilization period; determination of a temperature drift based on the measurement; and modification of a growth temperature based on a temperature offset determined in response to the temperature drift exceeding a threshold criteria. In an embodiment, a statistic derived from a plurality of pyrometric measurements made during the recipe stabilization over several runs is employed to offset each of a set of growth temperatures utilized to form a multiple quantum well (MQW) structure.

### CROSS REFERENCE TO RELATED APPLICATIONS

This application claims the benefit of U.S. Provisional Application No. 61/383,669 (Attorney Docket No. 014874/L2/ALRT/AEP/NEON/ESONG) filed on Sep. 16, 2010, entitled “EPITAXIAL GROWTH TEMPERATURE CONTROL IN LED MANUFACTURE,” the entire contents of which are hereby incorporated by reference in its entirety for all purposes.

### BACKGROUND

1. Field

Embodiments of the present invention pertain to the field of light-emitting diode (LED) fabrication and, in particular, to growth of multi-junction LED film stacks.

2. Description of Related Art

Group III-V materials are playing an ever increasing role in the semiconductor and related, e.g. light-emitting diode (LED), industries. While LEDs employing multiple quantum well (MQW) structures epitaxially grown on a substrate are a promising technology, epitaxial growth of such structures is difficult because of the large number of very thin material layers formed and the dependence of emission wavelength on the material and physical characteristics of those layers.

The material and/or physical characteristics of an MQW structure are dependent on the growth environment within an epitaxy chamber which can vary over a number batches or runs processed. Growth temperature, for example, varies as the emissivity of the chamber walls varies over time and/or with the number of runs. However, closed loop control of growth temperature during growth of an MQW structure is very challenging in part because noise in growth temperature observation coupled with the growth temperature modulation typical between alternate barrier and well layers of an MQW structure and the short duration of each MQW layer growth can often lead to over control and instability.

### BRIEF DESCRIPTION OF THE DRAWINGS

Embodiments of the present invention is illustrated by way of example, and not by way of limitation, in the figures of the accompanying drawings, in which:

FIG. 1A illustrates a cross-sectional view of a GaN-based LED film stack which is grown using the growth temperature control method depicted in FIG. 1A, in accordance with an embodiment of the present invention;

FIG. 1B is a graph illustrating a chamber temperature drift over a number of MQW growths;

FIG. 1C is a flow diagram illustrating a general method for epitaxial growth temperature control, in accordance with an embodiment of the present invention;

FIG. 1D is a flow diagram illustrating a method for epitaxial growth temperature control, in accordance with an MQW embodiment of the present invention;

FIG. 2A is a graph illustrating an observed growth temperature over time during an epitaxial growth of an MQW structure, in accordance with an embodiment of the present invention;

FIG. 2B is a graph of a growth temperature observed during a stabilization period prior to the MQW growth when no temperature offset is employed.

FIG. 2C is a graph of a growth temperature observed during a stabilization period prior to the MQW growth when a temperature offset is employed, in accordance with an embodiment of the present invention;

FIG. 3 is a schematic cross-sectional view of an HVPE apparatus, in accordance with an embodiment of the present invention;

FIGS. 4A and 4B are schematic cross-sectional views of an MOCVD apparatus, in accordance with an embodiment of the present invention; and

FIG. 5 is a schematic of a computer system, in accordance with an embodiment of the present invention.

### SUMMARY

Light-emitting diodes (LEDs) and related devices may be fabricated from layers of group III-V films. Exemplary embodiments of the present invention relate to the growth of LED junctions in group III-nitride films, such as, but not limited to gallium nitride (GaN) films.

Disclosed herein are apparatuses and method for control of epitaxial growth temperatures during manufacture of light emitting diodes (LEDs). Embodiments include in-situ measurement of a substrate or carrier temperature while the substrate and/or carrier is disposed within the epitaxy chamber during a recipe stabilization period. A temperature drift may be determine based on the temperature measurement and a growth temperature setpoint defined in a process recipe file and a growth temperature then modified by a temperature offset determined in response to the temperature drift satisfying a threshold criteria.

In an embodiment, a statistic derived from a plurality of pyrometric measurements made during a recipe stabilization period is employed to offset each of a set of growth temperatures utilized to form a multiple quantum well (MQW) structure. In embodiments, this fixed offset is employed for successive growths performed in the chamber until the temperature drift is subsequently determined to again satisfy the threshold criteria.

Embodiments include epitaxy chambers and systems which include a contactless temperature sensor, such as a pyrometer, disposed external to the epitaxy chamber to measure, through a window in the chamber, a temperature of the substrate or carrier when disposed within the epitaxy chamber. A mechanical shutter may be provided between the window and the substrate or carrier to be opened during a recipe stabilization period to permit substrate or carrier temperature observation and closed during the MQW growth to protect the window from deposits.

In embodiments, a system controller is to receive a temperature measurement prior to commencing growth of the MQW and to determine a temperature drift by subtracting the measured temperature from an initial growth temperature setpoint. The system controller is to offset the initial growth temperature setpoint to reduce the temperature drift in response to determining that the magnitude of the temperature drift satisfies a threshold criteria

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

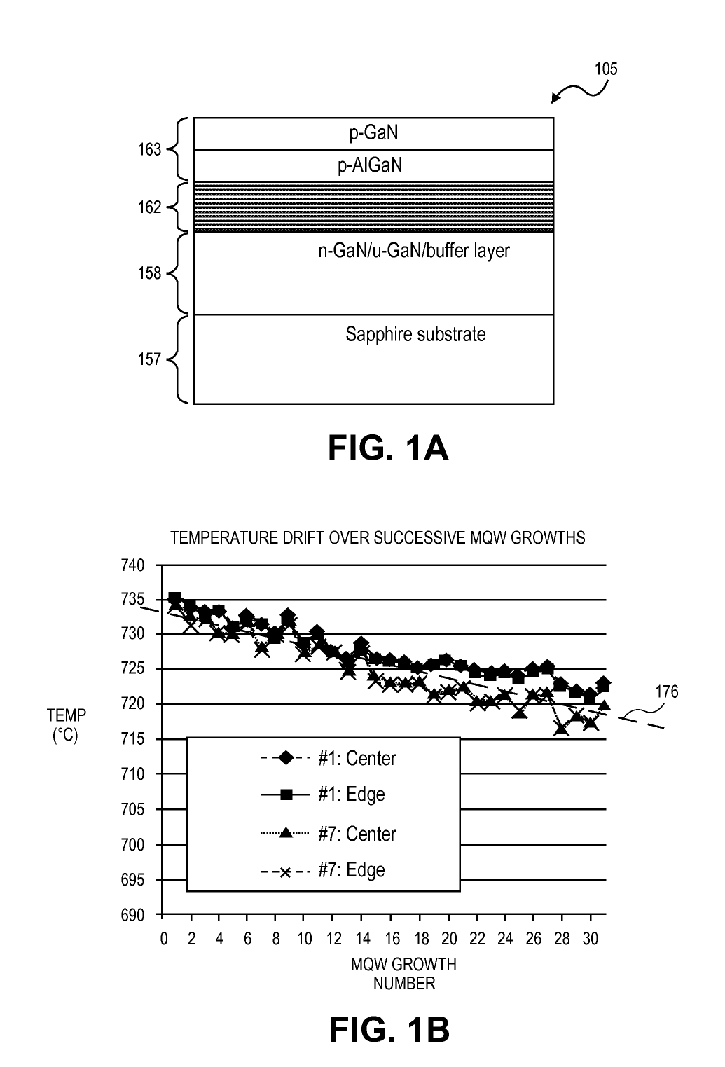

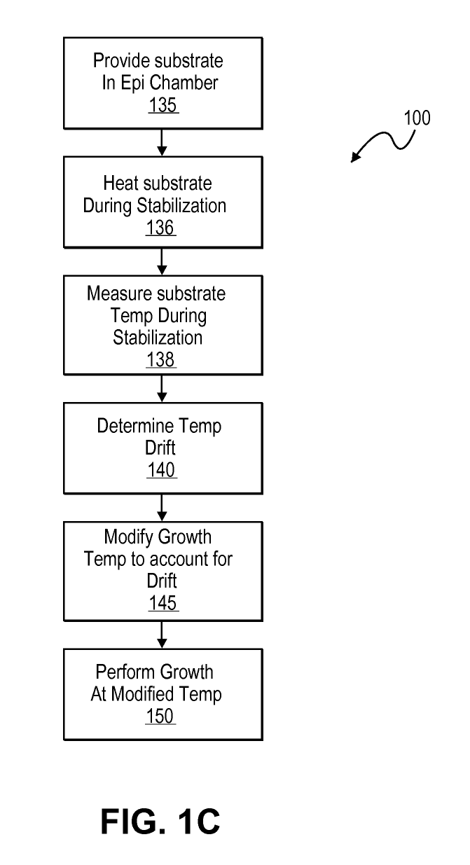

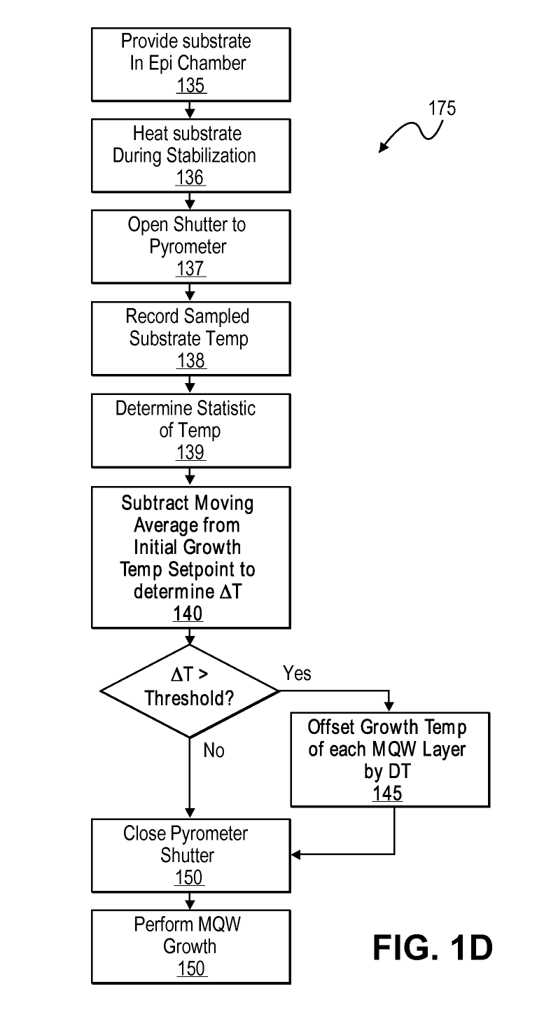

FIG. 1A illustrates a cross-sectional view of a GaN-based LED film stack which is grown using the growth temperature control method depicted in FIG. 1A, in accordance with an embodiment of the present invention. Depending on the embodiment, all layers in a III-V or II-VII structure, such as that depicted in FIG. 1A, are grown with a single chamber process or a multiple chamber process. For a single chamber process, layers of differing composition are grown successively as different steps of a growth recipe executed within the single chamber. For a multiple chamber process, layers in a III-V or II-VII structure, such as that depicted in FIG. 1A, are grown in a sequence of separate chambers. For example, and undoped/nGaN layer grown in a first chamber, a MQW structure in a second chamber, and a pGaN layer grown in a third chamber.

In FIG. 1A, an LED stack 105 is formed on a substrate 157. In one implementation, the substrate 157 is single crystalline sapphire. Other embodiments contemplated include the use of substrates other than sapphire substrates, such as, Silicon (Si), germanium (Ge), silicon carbide (SiC), gallium arsenide (GaAs), zinc oxide (ZnO), lithium aluminum oxide (γ-LiAlO₂). Upon the substrate 157, is one or more base layers 158 which may include any number of group III-nitride based materials, such as, but not limited to, GaN, InGaN, AlGaN. The substrate and buffer layers may provide either a polar GaN starting material (i.e., the largest area surface is nominally an (h k l) plane wherein h=k=0, and l is non-zero), a non-polar GaN starting material (i.e., the largest area surface oriented at an angle ranging from about 80-100 degrees from the polar orientation described above towards an (h k l) plane wherein l=0, and at least one of h and k is non-zero), or a semi-polar GaN starting material (i.e., the largest area surface oriented at an angle ranging from about >0 to 80 degrees or 110-179 degrees from the polar orientation described above towards an (h k l) plane wherein l=0, and at least one of h and k is non-zero). One or more bottom n-type epitaxial layers are further included in the base layer 158 to facilitate a bottom contact. The bottom n-type epitaxial layers may be any doped or undoped n-type group III-nitride based materials, such as, but not limited to, GaN, InGaN, AlGaN.

As further depicted in FIG. 1A, a multiple quantum well (MQW) structure 162 is disposed over the base layer 158. The MQW structure 162 may be any known in the art to provide a particular emission wavelength. In a certain embodiments, the MQW structure 162 may have a wide range of indium (In) content within GaN. For example, depending on the desired wavelength(s), the MQW structure 162 may have between about a 10% to over 40% of mole fraction indium as a function of growth temperature, ratio of indium to gallium precursor, etc. It should also be appreciated that any of the MQW structures described herein may also take the form of single quantum wells (SQW) or double hetereostructures that are characterized by greater thicknesses than a QW. The base layer 158 and MQW structure 162 may be grown in a metalorganic chemical vapor deposition (MOCVD) chamber or a hydride/halide vapor phase epitaxy (HVPE) chamber, or another known in the art. Any growth techniques known in the art may be utilized with such chambers.

One or more p-type epitaxial layers 163 are disposed over the bottom MQW structure 162. The p-type epitaxial layers 163 may include one or more layers of differing material composition. In the exemplary embodiment, the p-type epitaxial layers 163 include both p-type GaN and p-type AlGaN layers doped with Mg. In other embodiments only one of these, such as p-type GaN are utilized. Other materials known in the art to be applicable to p-type contact layers for GaN systems may also be utilized. The thicknesses of the p-type epitaxial layers 163 may also vary within the limits known in the art. The p-type epitaxial layers 163 may also be gown in an MOCVD or HVPE epitaxy chamber. Incorporation of Mg during the growth of the p-type epitaxial layers 163 may be by way of introduction of cp₂Mg to the epitaxy chamber, for example. In an embodiment, the p-type epitaxial layers 163 are grown using the same epitaxial chamber as was used for the bottom MQW structure 162.

Additional layers, such as, tunneling layers, n-type current spreading layers and further MQW structures (e.g., for stacked diode embodiments) may be disposed on the stack 105 in substantially the same manner described for the layers 158, 162 and 163 or in any manner known in the art. Following the growth of the LED stack 105, the substrate is unloaded from the growth platform and conventional patterning and etching techniques are performed to expose regions of the bottom n-type GaN layers (e.g., top surface of starting material 158) and the p-type epitaxial layers 163. Any contact metallization known in the art may then be applied to the exposed regions to form n-type electrode contact and p-type electrode contacts for the LED stack 105. In exemplary embodiments, the n-type electrode is made of a metal stack, such as, but not limited to, Al/Au, Ti/Al/Ni/Au, Al/Pt/Au, or Ti/Al/Pt/Au. Exemplary p-type electrode embodiments include Ni/Au or Pd/Au. For either n-type or p-type contacts, a transparent conductor, such as Indium Tin Oxide (ITO), or others known in the art, may also be utilized.

FIG. 1B is a graph illustrating an epitaxial chamber temperature drift over a number of MQW structure growths. As shown, each growth of the MQW structure 162 induces a change in observed or measured temperature of a substrate or a substrate carrier supporting a plurality of substrates within the deposition chamber for batch processing. In this context, a “substrate” is that under which an epitaxial layer is formed. Thus, a substrate upon which the MQW structure 162 is grown includes the substrate 157 and base layer 158 while a substrate upon which the p-type layers 163 are formed includes the substrate 157, the base layer 158, and the MQW structure 162.

In FIG. 1B, a linear fit 176 models the temperature drift over approximately 30 growths of the MQW structure 162 performed successively in a single epitaxy chamber. It has been found that for certain LED stacks, such as the LED stack 105, the emission wavelength of the LED varies by approximately 0.5 nm/° C. As such, the drift illustrated in FIG. 1B will induce an 8-10 nm shift over 30 substrates. In an embodiment, this temperature drift is corrected based on in-situ temperature observation to provide improved control of the MQW growth temperature. As used herein, “in-situ” temperature observation refers to temperature measurements made while the substrate is disposed within the deposition chamber that is to grow the MQW structure 162.

In an embodiment, in-situ measurement data is used to detect a process temperature drift and a closed loop feedback control system is to then make a real-time adjustment in the film growth temperature as required to reduce or eliminate the temperature drift's influence on the emission wavelength of an LED stack to be grown on the substrate. In one embodiment, a real-time “feedback” adjustment entails modifying an initial growth temperature (i.e., that temperature which is observed in-situ) prior to growing at least one of the material layers making up the MQW structure 162 for the substrate for which the temperature was measured. In an alternative embodiment, in-situ measurement data from a first substrate is used to detect a process temperature drift associated with the chamber state and a feedforward control loop is to then make a growth temperature adjustment as required to reduce or eliminate the effect the temperature drift will have on the emission wavelength of an LED stack grown on a subsequent substrate. In one such embodiment, a “feed-forward” adjustment entails modifying a growth temperature prior to growing at least one of the material layers making up the MQW structure 162 for a substrate processed subsequent to the substrate of which the temperature was measured.

FIG. 1C is a flow diagram illustrating a general method 100 for epitaxial growth temperature control, in accordance with an embodiment of the present invention. FIG. 1D is a flow diagram illustrating a method 175 for epitaxial growth temperature control, in accordance with an MQW embodiment of the present invention. The method 175 is to be understood as a specific example of the more general method 100.

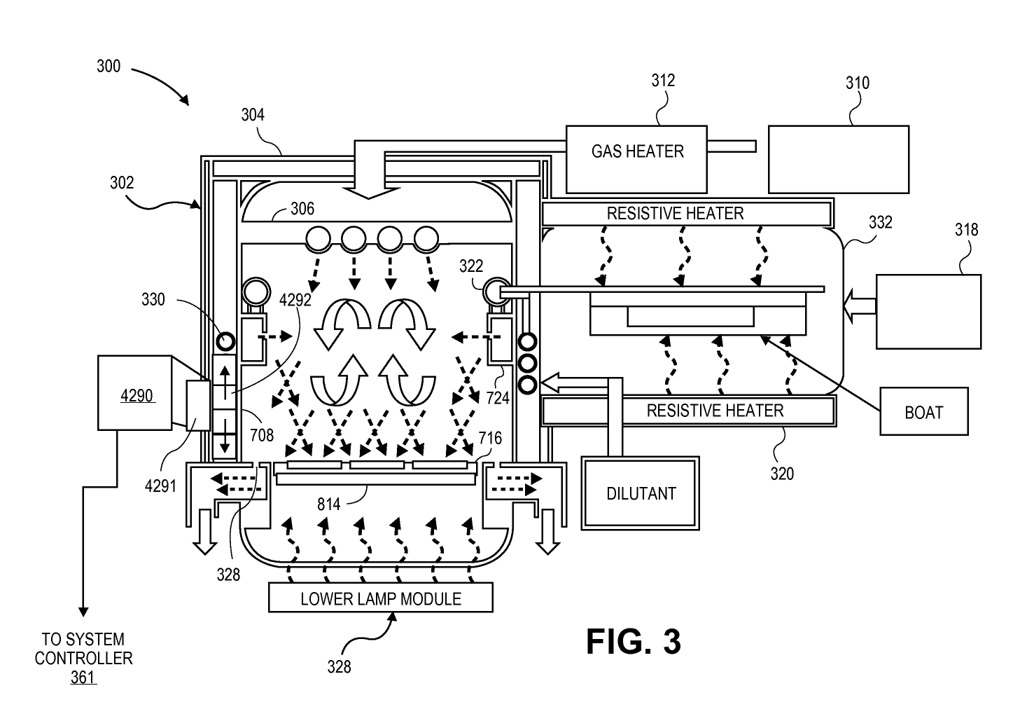

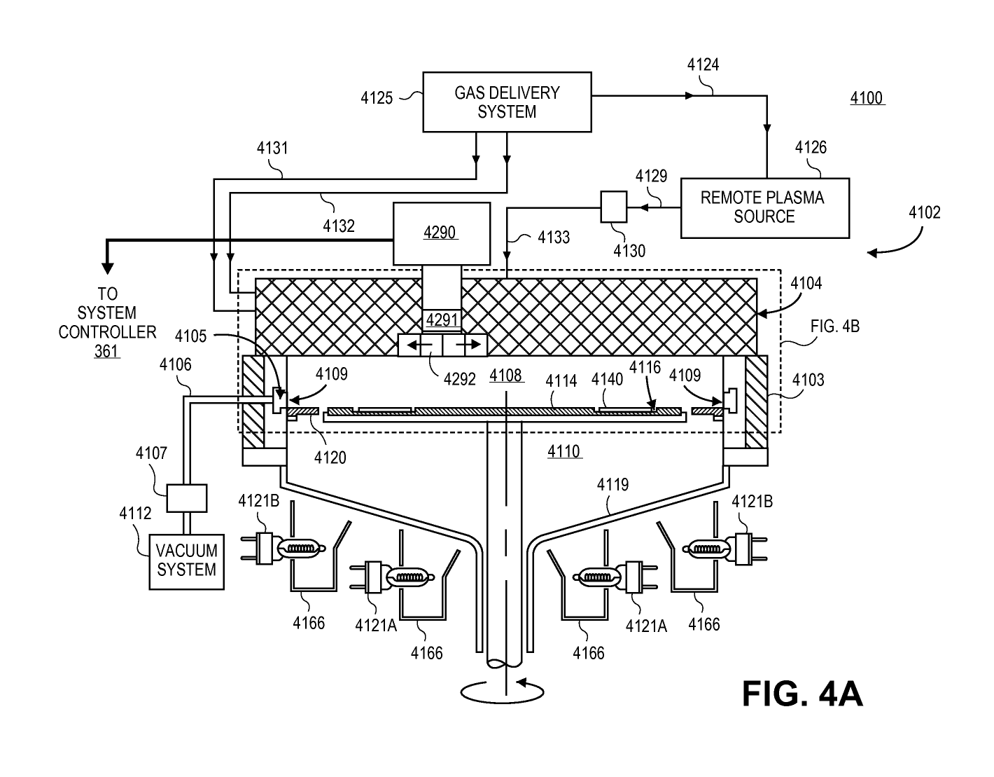

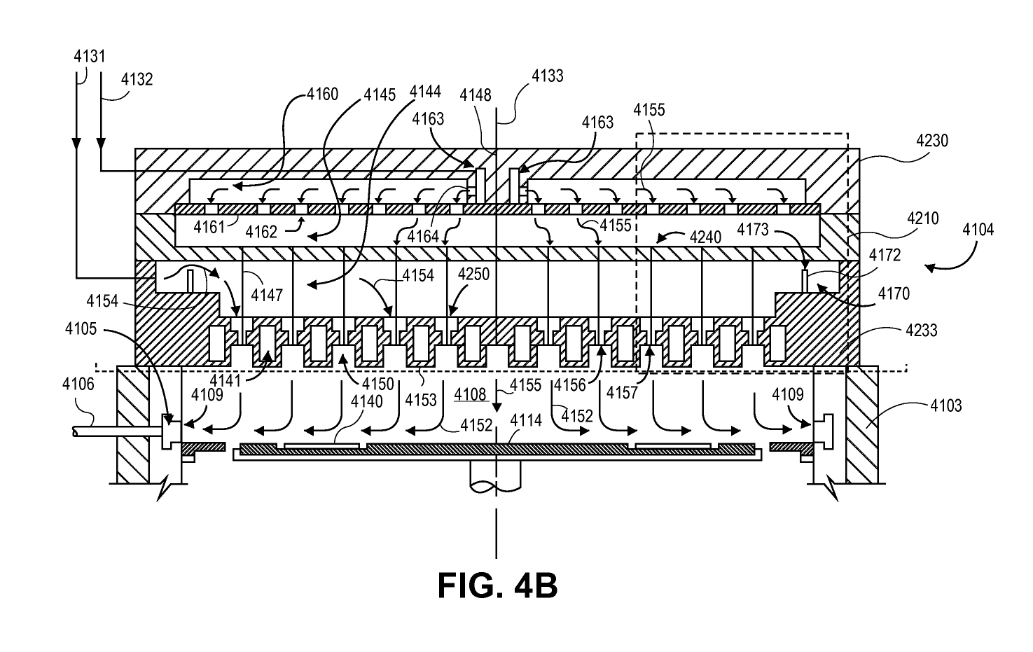

Referring first to FIG. 1C, at operation 135, a substrate is provided in a deposition chamber 135, such as one of those further described in FIG. 3, FIGS. 4A, 4B, or any other commercially available chamber. At operation 136 the substrate is heated to an initial growth temperature setpoint, which for example may be defined in a growth process recipe file stored in a memory of a system controller. The substrate heating may be performed in any manner known in the art. While the substrate is being heated, a temperature is measured at least once at operation 138. The temperature may be observed in-situ with any contactless measurement technique known in the art. In one embodiment, the temperature measurement at operation 138 is a pyrometric measurement performed with a pyrometer disposed external to the deposition chamber. The pyrometer is positioned with a line of sight view of either the substrate or a carrier upon which the substrate is disposed within the deposition chamber. The carrier is also heated to a same or relatable temperature as that of the substrate. In alternative embodiments, an IR imaging sensor may be employed to measurement the substrate temperature at operation 138. In other embodiments, the temperature measurement at operation 138 may be performed with a microwave reflectance tool, such as one commercially available from Lehighton, from which a resistivity determination may be made and then correlated to temperature. In still other embodiments where the growth temperature is not prohibitive (e.g., for low temperature growths), in-situ photo luminescence (PL) may also be performed to determine the substrate temperature. Other embodiments utilize a technique known as band edge thermometry.

In embodiments, the substrate temperature measurement is performed during a recipe stabilization period prior to an epitaxial growth portion of the recipe. For example, for growth of a first material layer of the MQW structure 162, the base layer 158 is the uppermost material layer on the substrate during the measurement at operation 138. During the recipe stabilization time, no material growth is occurring and the substrate is stabilizing to an initial growth temperature even though the temperature setpoint may be varied over time during the stabilization period in an effort to most quickly stabilize the temperature at the initial growth temperature setpoint.

At operation 140 the temperature drift is determined at operation 140 based on a comparison of the initial growth temperature setpoint or target value (e.g., determined from recipe file) and the initial growth temperature measured at operation 138. Where the measured initial growth temperature deviates sufficiently from the initial growth temperature setpoint, a process variable correction is made during the growth following the recipe stabilization time. At operation 145, the growth temperature setpoint is modified from the initial growth temperature setpoint to offset the measured initial growth temperature during a balance of the recipe stabilization period to account for the temperature drift quantified at operation 140 prior to commencing growth.

At operation 150 the epitaxial growth is performed at the modified growth temperature. Any conventional growth may be performed using any known techniques. In particular embodiments, the epitaxial growth performed at the modified growth temperature occurs within a time period that is less than the time period over which the substrate temperature was measured during the recipe stabilization period. As such, the modified growth temperature is based on an initial growth temperature observation that is subject to less noise. In particular embodiments, no temperature measurement of the substrate or carrier is performed during the growth operation 150. For example, where a pyrometer is utilized during operation 140, a shutter isolates the pyrometer from the substrate or carrier during operation 150 such that no pyrometric measurement is possible.

Turning now to FIG. 1D, the method 175 is described in conjunction with exemplary hardware which may be employed in performance of the method to form the MQW 162 of FIG. 1A. At operation 135, a substrate including a GaN base layer 158 is provided an epitaxial deposition chamber. The epitaxy chamber may be as depicted in FIG. 3, FIGS. 4A, 4B, or any other commercially available chamber.

As in method 100, at operation 136 the substrate is heated during the recipe stabilization period. Upon an event, such as, expiration of a timer, a shutter is opened at operation 138 to allow observation of the heated substrate or carrier by a temperature metrology tool disposed external to the deposition chamber. The shutter may be any mechanical component known in the art which can be disposed between a window transparent to the temperature metrology tool and the substrate or substrate carrier to be observed. For example, an HVPE apparatus 300 depicted in FIG. 3, includes a shutter 4292 disposed between the window 4291 and the chamber 302. In the exemplary embodiment, a pyrometer 4290 is disposed external to the window 4291 and upon the shutter 4292 opening, temperature readings may begin being sampled at operation 138 (FIG. 1D). Similarly, in FIG. 4A an MOCVD apparatus configured with in-situ temperature measurement hardware including the pyrometer 4290, window 4291 and shutter 4292 is illustrated. Generally, a pyrometer measurement can be sampled between 5 and 10 times/minute and in particular embodiments the shutter may be held open to allow a plurality of pyrometer measurements. For example, the shutter 4292 may be held open for between 15 and 30 seconds and between 2 and 6 temperature measurements recorded. Following the temperature measurements, the shutter 4292 is closed in preparation for the growth portion of the process recipe being executed.

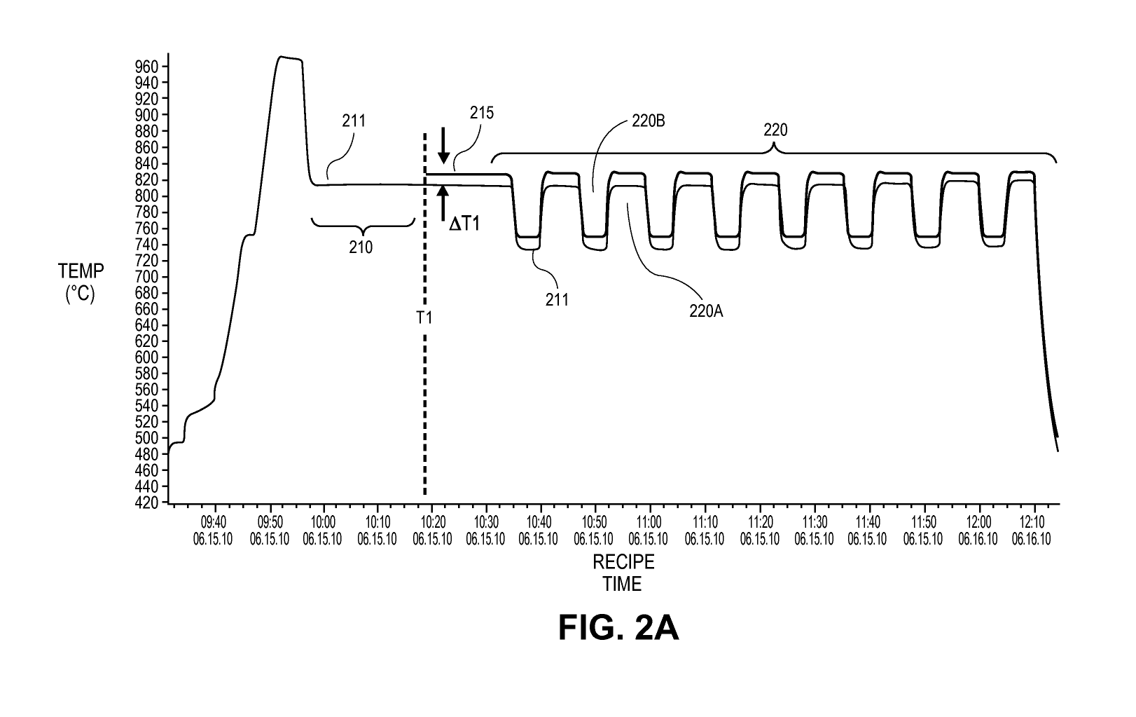

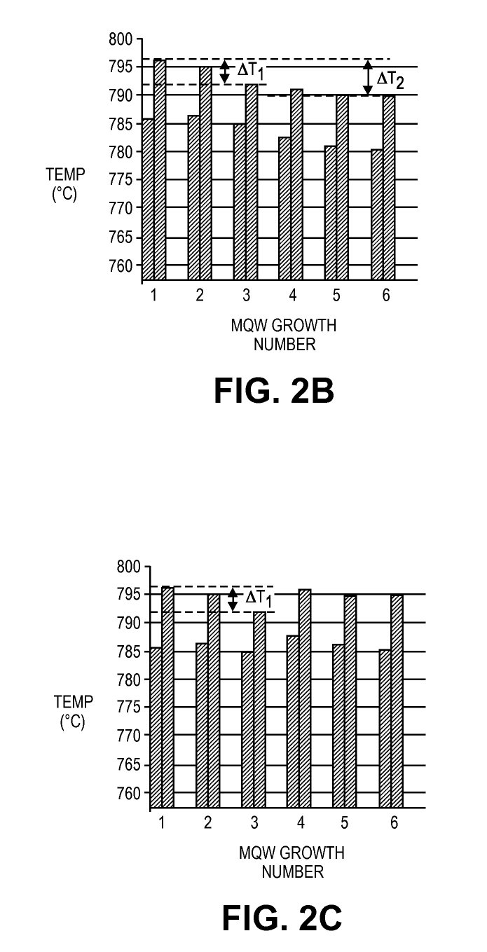

FIG. 2A is a graph illustrating a growth temperature observed over time during a single MQW epitaxial growth run, in accordance with an embodiment of the present invention. In this embodiment, the measurement operation 138 is performed during a recipe stabilization time 210. During the recipe stabilization time 210, no material growth is occurring and the substrate is stabilizing to an initial MQW growth temperature 211 (e.g., ˜810° C.) even though the temperature setpoint may be varied over time.

Returning to FIG. 1D, at operation 139, a statistic of the temperature measurements recorded at operation 138 is generated. In certain embodiments where the shutter 4292 is open for between 15 and 30 seconds, the 2-6 temperatures measurements collected are averaged. In other embodiments where the shutter 4292 is open for 30 seconds to 10 or more minutes during the recipe stabilization time 210, a moving average of temperature is determined, where the moving average T̅_{ι} is defined as:

$${\overline{T}}_{i} = \frac{{\sum }_{i = 1}^{n} {T}_{i}}{n} , \qquad ( 1 )$$

with n being the number of temperature samples Tᵢ collected by the pyrometer 4290 over a set time slice of the total duration the shutter 4292 is open. For example, where the shutter is open for 10 minutes and n is equal to 5 measurements taken every 30 seconds, there are 20 values T̅_{ι}, each averaged over 5 samples. In further embodiments, where a plurality of temperature measurements are recorded or a plurality of temperature statistics, such as a rolling average, are generated, a system controller generates a model fit of the individual measurements or measurement statistics to further reduce noise in the temperature observation. For example a liner regression of the individual temperature measurements or temperature statistics vs. time may be performed by the system controller to arrive at a function from which the temperature near the end of the stabilization period may be estimated.

At operation 140, a single temperature measurement from operation 138, a temperature statistic from operation 139 (e.g., last determined moving average or modeled estimate of the temperature), or a model estimated temperature is compared to the initial growth temperature setpoint to determine a temperature error (c) for the upcoming MQW growth. In an embodiment a temperature difference, ΔT=T_{initial setpoint}−T_{measured}, where T_{measured} is either single temperature measurement from operation 138, a temperature statistic or a modeled temperature estimate from operation 139. In one embodiment, where the initial growth temperature setpoint is expected to be higher because the chamber temperature is drifting downward with use, as illustrated in FIG. 1B, the temperature difference ΔT is a positive number.

In further embodiments, a run-to-run temperature statistic is generated based temperature measurements made at operation 138 over a plurality of successive growth runs, based on temperature statistics generated at operation 139 over a plurality of successive growth runs, or based on model estimated temperatures generated over a plurality of successive growth runs. Where run-to-run statistics are generated, the statistic or model of the run-to-run trend is used to generate a predicted growth temperature for the upcoming MQW growth. The predicted growth temperature may then be compared to the initial growth temperature setpoint to generate an estimated ΔT. For example, where a moving average of temperature generated at operation 139 is collected over a plurality of successive MQW growth runs, a fit of the plurality of moving average values may be made to generate a model of temperature as a function of run number. A model akin to the linear model 176 may then be used to quantify chamber temperature drift and estimate the temperature for the upcoming MQW growth rather than relying solely on the measurements being taken during the stabilization period of a single run. As another example, a run-to-run statistic such as average ΔT over the last n runs (e.g., slope of linear model 176) may be generated and utilized for quantification of chamber temperature drift.

Next, at operation 142, the quantified temperature drift is compared with a threshold criteria. The threshold criteria is predetermined and is generally a function of the signal to noise ratio of the temperature measurement. Only where the temperature drift determined at operation 140 satisfies the threshold criteria is system controller to react by offsetting the growth temperature at operation 145. Where the temperature drift determined at operation 140 fails to satisfy the threshold criteria at operation 142, the method 175 advances to operation 150 and the MQW structure is grown at the initial growth temperature setpoint.

Where the temperature drift determined at operation 140 satisfies the threshold criteria at operation 142, the method 175 advances to operation 145 and the growth temperature is modified based on the measured temperature. In particular embodiments, the growth temperature of each MQW layer is offset by an amount dependent on the comparison made at operation 142. In one embodiment where the temperature drift exceeds a ΔT threshold at operation 142, the growth temperature of each MQW layer is offset by the ΔT threshold (T_{modified}=T_{initial setpoint}+ΔT_{threshold}). In another embodiment, the thresholding serves only to dampen the control response and the growth temperature of each MQW layer is offset from the initial growth temperature setpoint by a function of the difference between the measured temperature and initial growth setpoint temperature (T_{modified}=T_{initial setpoint}+f(ΔT)). In a particular embodiment, the growth temperature of each MQW layer is offset by the actual difference between the measured temperature and initial growth setpoint temperature (T_{modified}=T_{initial setpoint}+ΔT).

Referring to FIG. 2A for example, after the observation during recipe stabilization period 210, the growth temperature setpoint may be modified so that a MQW growth 220 is performed at a modified growth temperature 215 more closely matching the growth temperature of a previous run and/or more closely matching the initial growth temperature setpoint defined in the recipe file. As of the time T1, the modified growth temperature 215 is offset from the initial measured growth temperature 211 by an amount ΔT1 for each of the plurality of barrier layers 220A and wells 220B in the MQW 220 (the curve representing the initial growth temperature 211 is depicted for times greater than T1 only for the purpose of illustrating the temperature offset).

In other embodiments, process parameters other than the temperature setpoint are offset from a nominal initial value based on a difference between the measured initial growth temperature and initial growth temperature setpoint. For example, feed gas ratios may be modified from baseline growth recipe setpoints during the MQW growth 220 to account for the temperature drift quantified at operation 140. (e.g., as depicted for ΔT1 in FIG. 2A).

At operation 147, the initial growth temperature setpoint value is updated to be the modified growth temperature and repetition of the method 175 proceeds with the growth temperature incrementing from the previous run's temperature setpoint by an offset for each run (e.g., ΔTᵣᵤₙ=Tᵣᵤₙ₋₁−T_{run,measured}), where Tᵣᵤₙ₋₁, initial is the modified growth temperature of the previous run, if the incremental drift from the prior run satisfies the threshold criteria (e.g., Tᵣᵤₙ₋₁−T_{run,measured}>ΔT_{threshold}) during the recipe stabilization period. With the offset for each run dependent on the previous run, a given calculated temperature offset value will typically be applied to a few successive runs each time the drift threshold is exceeded. Alternatively, the initial growth temperature setpoint value is not equated to the modified growth temperature at operation 147 and repetition of the method 175 proceeds with the growth temperature offset for each run determined based on the same nominal initial growth temperature setpoint (e.g., ΔTᵣᵤₙ=T_{initial setpoint}−T_{i,measured}) if the drift from the initial set point satisfies the threshold criteria (e.g., T_{initial setpoint}−T_{run,measured}>ΔT_{threshold}). With the offset for each run independent, a temperature offset is separately calculated and applied for each run subsequent to a first run satisfying the drift threshold.

At operation 150, the MQW structure 162 is grown at the modified growth temperature using any techniques known in the art. In particular embodiments, the growth of each semiconductor layer in the MQW structure is grown within a time period that is shorter than the time period over which the substrate temperature was measured during the recipe stabilization period. As such, the modified growth temperature utilized for each of the plurality of MQW layers may be based on an initial growth temperature observation that is subject to less noise than a control loop which attempts temperature control during the MQW layer growth.

FIG. 2B is a graph of a growth temperature observed during a stabilization period prior to the MQW growth when no temperature offset is employed. Over the course of 6 MQW growth runs, the growth temperature drops from an initial temperature setpoint of 796° C. on the first run to (796° C.−ΔT1) at run 3 to (796° C.−ΔT2) at run 6. In comparison, FIG. 2C is a graph of a growth temperature observed during a stabilization period prior to the MQW growth when a temperature offset is employed, in accordance with an embodiment of the present invention. Here, the growth temperature again drops from the initial growth temperature setpoint by an amount ΔT1 at run 3, but a temperature drift threshold criteria then becomes satisfied at run 4 and, in response, the system controller modifies the growth temperature by a temperature offset equal to ΔT1 to make the growth temperature of run 4 be substantially equal to that of run 1. Runs 5 and 6 are similarly closer to the temperature of run 1 than they would have been absent the correcting temperature offset (as shown in FIG. 2B). Eventually, a second correction will be made as the MQW growth run count progresses to run 7, 8, 9, etc.

With growth temperature correction methods 100 and 175 described, hardware components of the deposition chambers in FIGS. 3, 4A and 4B are now described in more detail. Referring first to FIG. 3, a processing gas from a first gas source 310 is delivered to the chamber 302 through a gas distribution showerhead 306. In one embodiment, the gas source 310 may comprise a nitrogen containing compound. In another embodiment, the gas source 310 may comprise ammonia. In one embodiment, an inert gas such as helium or diatomic nitrogen may be introduced as well either through the gas distribution showerhead 306 or through the walls 308 of the chamber 302. An energy source 312 may be disposed between the gas source 310 and the gas distribution showerhead 306. In one embodiment, the energy source 312 may comprise a heater. The energy source 312 may break up the gas from the gas source 310, such as ammonia, so that the nitrogen from the nitrogen containing gas is more reactive.

To react with the gas from the first source 310, precursor material may be delivered from one or more second sources 318. The precursor may be delivered to the chamber 302 by flowing a reactive gas over and/or through the precursor in the precursor source 318. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 332 and be heated with the resistive heater 320. By increasing the residence time that the chlorine containing gas is snaked through the chamber 332, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 320 within the second chamber 332 in a boat. The chloride reaction product may then be delivered to the chamber 302. The reactive chloride product first enters a tube 322 where it evenly distributes within the tube 322. The tube 322 is connected to another tube 324. The chloride reaction product enters the second tube 324 after it has been evenly distributed within the first tube 322. The chloride reaction product then enters into the chamber 302 where it mixes with the nitrogen containing gas to form a nitride layer on the substrate 316 that is disposed on a susceptor 314. In one embodiment, the susceptor 314 may comprise silicon carbide. The nitride layer may comprise gallium nitride for example. The other reaction products, such as nitrogen and chlorine, are exhausted through an exhaust 326.

Turning to FIG. 4A, a schematic cross-sectional view of an MOCVD chamber which can be utilized in embodiments of the invention is depicted. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The MOCVD apparatus 4100 shown in FIG. 4A comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrates 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104, as described herein, may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, MOCVD apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as III-V films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

FIG. 4B is a detailed cross sectional view of the showerhead assembly shown in FIG. 4A, in accordance with an embodiment of the present invention. The showerhead assembly 4104 is located near the substrate carrier 4114 during substrate 4140 processing. In one embodiment, the distance from the showerhead face 4153 to the substrate carrier 4114 during processing may range from about 4 mm to about 41 mm. In one embodiment, the showerhead face 4153 may comprise multiple surfaces of the showerhead assembly 4104 which are approximately coplanar and face the substrates 4140 during processing.

During substrate 4140 processing, according to one embodiment of the invention, process gas 4152 flows from the showerhead assembly 4104 towards the substrate 4140 surface. The process gas 4152 may comprise one or more precursor gases as well as carrier gases and dopant gases which may be mixed with the precursor gases. The draw of the annular exhaust channel 4105 may affect gas flow so that the process gas 4152 flows substantially tangential to the substrates 4140 and may be uniformly distributed radially across the substrate 4140 deposition surfaces in a laminar flow. The processing volume 4108 may be maintained at a pressure of about 360 Torr down to about 80 Torr.

Reaction of process gas 4152 precursors at or near the substrate 4140 surface may deposit various metal nitride layers upon the substrate 4140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

In one embodiment, the showerhead assembly 4104 comprises an annular manifold 4170, a first plenum 4144, a second plenum 4145, a third plenum 4160, gas conduits 4147, blocker plate 4161, heat exchanging channel 4141, mixing channel 4150, and a central conduit 4148. The annular manifold 4170 encircles the first plenum 4144 which is separated from the second plenum 4145 by a mid-plate 2210 which has a plurality of mid-plate holes 4240. The second plenum 4145 is separated from the third plenum 4160 by blocker plate 4161 which has a plurality of blocker plate holes 4162 and the blocker plate 4161 is coupled to a top plate 2230. The mid-plate 2210 includes a plurality of gas conduits 4147 which are disposed in mid-plate holes 2240 and extend down through first plenum 4144 and into bottom plate holes 2250 located in a bottom plate 2233. The diameter of each bottom plate hole 4250 decreases to form a first gas injection hole 4156 which is generally concentric or coaxial to gas conduit 4147 which forms a second gas injection hole 4157. In another embodiment, the second gas injection hole 4157 may be offset from the first gas injection hole 4156 wherein the second gas injection hole 4157 is disposed within the boundary of the first gas injection hole 4156. The bottom plate 4233 also includes heat exchanging channels 4141 and mixing channels 4150 which comprise straight channels which are parallel to each other and extend across showerhead assembly 4104.

The showerhead assembly 4104 receives gases via supply lines 4131, 4132, and 4133. In another embodiment, each supply line 4131, 4132 may comprise a plurality of lines which are coupled to and in fluid communication with the showerhead assembly 4104. A first precursor gas 4154 and a second precursor gas 4155 flow through supply lines 4131 and 4132 into annular manifold 4170 and top manifold 4163. A non-reactive gas 4151, which may be an inert gas such as hydrogen (H₂), nitrogen (N₂), helium (He), argon (Ar) or other gases and combinations thereof, may flow through supply line 4133 coupled to a central conduit 4148 which is located at or near the center of the showerhead assembly 4104. The central conduit 4148 may function as a central inert gas diffuser which flows a non-reactive gas 4151 into a central region of the processing volume 4108 to help prevent gas recirculation in the central region. In another embodiment, the central conduit 4148 may carry a precursor gas.

The HVPE apparatus 300 and/or the MOCVD apparatus 4100 may be used in a processing system which comprises a cluster tool that is adapted to process substrates and analyze the results of the processes performed on the substrate. The cluster tool is a modular system comprising multiple chambers that perform various processing steps that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

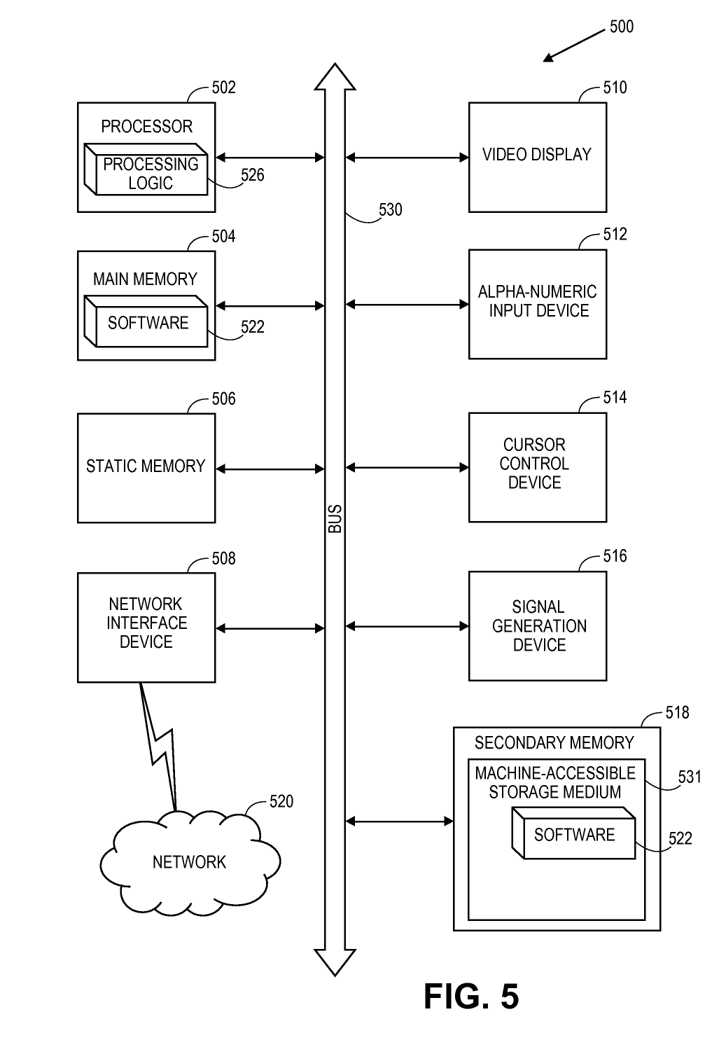

FIG. 5 illustrates a diagrammatic representation of a machine in the exemplary form of a computer system 500 which may be utilized by the system controller 361 to control one or more of the operations, process chambers or multi-chambered processing platforms described herein. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the process operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methods or functions described herein. The software 522 may also reside, completely or at least partially, within the main memory 504 and/or within the processor 502 during execution thereof by the computer system 500, the main memory 504 and the processor 502 also constituting machine-readable storage media.

The machine-accessible storage medium 531 may further be used to store a set of instructions for execution by a processing system and that cause the system to perform any one or more of the embodiments of the present invention. Embodiments of the present invention may further be provided as a computer program product, or software, that may include a machine-readable storage medium having stored thereon instructions, which may be used to program a computer system (or other electronic devices) to perform a process according to the present invention. A machine-readable storage medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, and other such non-transitory storage media known in the art.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for epitaxially growing a semiconductor on a substrate, comprising:
providing a substrate in an epitaxy chamber;
heating the substrate during a process recipe stabilization period prior to film growth;
measuring the temperature of the substrate during the process recipe stabilization period;
determining a temperature drift by comparing the measured temperature to an initial growth temperature setpoint;
modifying a growth temperature setpoint by a temperature offset in response to the magnitude of the temperature drift satisfying a threshold criteria;
growing the semiconductor; and
removing the substrate from the epitaxy chamber.

2. The method of claim 1, wherein the semiconductor is grown on the substrate at the modified growth temperature.

3. The method of claim 1, wherein the modified growth temperature is equal to the initial growth temperature setpoint plus a function of the temperature offset.

4. The method of claim 2, wherein the modified growth temperature is equal to the initial growth temperature setpoint plus the temperature offset.

5. The method of claim 1, wherein measuring the temperature of the substrate comprises performing a pyrometric measurement.

6. The method of claim 5, wherein measuring the temperature of the substrate comprises performing a plurality of pyrometric measurements and determining a statistic of the pyrometric measurements.

7. The method of claim 6, wherein the statistic comprises a moving average of temperature, and wherein determining the temperature drift comprises subtracting a moving average value from the initial growth temperature.

8. The method of claim 1, wherein the semiconductor comprises a multiple quantum well (MQW) structure.

9. The method of claim 8, wherein growing the semiconductor further comprises modulating the growth temperature between a pair of initial growth temperature recipe setpoints as a plurality of alternating layers of the MQW structure are grown, and wherein each in the pair of initial growth temperature recipe setpoints is increased by the temperature offset.

10. The method of claim 9, wherein the growth of each semiconductor layer in the plurality is grown within a time period that is less than the time period over which the substrate temperature is measured.

11. A method for epitaxially growing a multiple quantum well (MQW) structure on a semiconductor substrate, comprising:
providing a GaN substrate in an epitaxy chamber;
heating the substrate during a process recipe stabilization period prior to film growth;
measuring the temperature of the substrate during the process recipe stabilization period;
determining a temperature drift by subtracting the measured temperature from an initial MQW growth temperature setpoint;
offsetting the initial MQW growth temperature setpoint to obviate the temperature drift upon the magnitude of the temperature drift satisfying a threshold criteria;
growing the MQW structure at the offset growth temperature; and
removing the substrate from the epitaxy chamber.

12. The method of claim 11, wherein the offset growth temperature is equal to the initial growth temperature setpoint plus the threshold criteria.

13. The method of claim 12, wherein measuring the temperature of the substrate comprises a plurality of pyrometric measurements and determining a moving average of the pyrometric measurements during the recipe stabilization period, and wherein the threshold criteria is greater than 1° C.

14. A system for epitaxially growing a semiconductor on a substrate, the system comprising:
an epitaxy chamber to grow an epitaxial layer on a semiconductor substrate;
a pyrometer external to the epitaxy chamber to measure, through a window in the chamber, a temperature of the substrate when disposed within the epitaxy chamber; and
a system controller to receive the measured temperature prior to commencing growth of the semiconductor and to determine a temperature drift by subtracting the measured temperature from an initial growth temperature setpoint, the system controller further to offset the initial growth temperature setpoint to reduce the temperature drift in response to determining that the magnitude of the temperature drift satisfies a threshold criteria.

15. The system of claim 14, further comprising a shutter disposed between the chamber window and the substrate, the shutter to open during the recipe stabilization and to close during the semiconductor growth.

16. The system of claim 14, wherein the system controller is to offset the initial growth temperature by an amount equal to the threshold criteria.

17. The system of claim 14, wherein the system controller is to determine a moving average of a plurality of the pyrometric measurements received during the recipe stabilization period.

18. The system of claim 17, wherein the system controller is to determine the temperature drift by subtracting the moving average from the initial growth temperature.

19. The system of claim 14, wherein the system controller is to modulate the growth temperature between a set of initial growth temperature recipe setpoints as a plurality of semiconductor layers of a multiple quantum well (MQW) structure is grown, and wherein the system controller is to increase each of the initial growth temperature recipe setpoints by a same temperature offset.

20. A computer readable storage media with instructions stored thereon, which when executed by a processing system, cause the system to perform the method of claim 1.
